(19) United States
(12) Patent Application Publication
(10) Pub. No.: US 2017/0055339 A1
(43) Pub. Date: Feb. 23, 2017

(54) THERMALLY CONDUCTIVE COMPOSITES AND METHODS OF MANUFACTURE THEREOF, AND ARTICLES CONTAINING THE COMPOSITES

(71) Applicant: ROGERS CORPORATION, Rogers, CT (US)

(72) Inventors: Li ZHANG, Winchester, MA (US); Murali SETHUMADHAVAN, Acton, MA (US)

(73) Assignee: Rogers Corporation, Rogers, CT (US)

(21) Appl. No.: 15/307,410

(22) PCT Filed: Apr. 24, 2015
(86) PCT No.: PCT/US2015/027431

§ 371 Date: Oct. 28, 2016

Related U.S. Application Data
(60) Provisional application No. 61/986,529, filed on Apr. 30, 2014.

(51) Int. Cl. H05K 1/02; H05K 1/03; C09K 5/14; C08K 3/38; C08K 7/04

(52) U.S. Cl. CPC H05K 1/0204; C08K 3/38; C08K 7/04; C09K 5/14; H05K 1/0373; C08K 2003/385; C08K 2201/004; C08K 2201/003; C08K 2201/011; C08K 2201/016; H05K 2201/026; H05K 2201/0209

(57) ABSTRACT

A thermally conductive composite includes a polymer; and boron nitride, wherein the boron nitride is in a form of a nanofiber, a nanotube, a nanoplate, or a combination thereof. Alternatively, a thermally conductive composite includes a boron nitride comprising pores; and a polymer disposed in a pore of the boron nitride.

### BACKGROUND

This disclosure relates to a thermally conductive composites, and methods of manufacture thereof.

Thermally conductive composites (a polymer and a filler) are used in a broad variety of applications, for example printed circuit boards. Printed circuit boards (PCBs) are used to mechanically support and electrically connect electronic components using conductive pathways laminated onto a non-conductive substrate. The electronic components generate heat. The heat can be dissipated through the PCB. Also, a heat sink can be used to dissipate heat from a component where the heat dissipating properties of the PCB are insufficient. To provide improved heat dissipation from electronic components, and to avoid the use of a heat sink, there remains a need for a PCB material with improved heat dissipating properties.

### BRIEF SUMMARY

Disclosed is a thermally conductive composite including: a polymer; and boron nitride, wherein the boron nitride is in a form of a nanofiber, a nanotube, a nanoplate, or a combination thereof.

Also disclosed is a thermally conductive composite including: a porous boron nitride; and a polymer disposed in a pore of the boron nitride.

A method of manufacturing the thermally conductive composite includes: combining a polymer, boron nitride, and a solvent to form a mixture; casting the mixture to form a layer; and removing the solvent to manufacture the thermally conductive composite.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a schematic of a single clad laminate;

FIG. 2 is a schematic of a double clad laminate;

FIG. 3 is a schematic of a double clad laminate with patterned conductive layer;

FIG. 4 is a schematic of an exemplary circuit assembly comprising two double clad circuit laminates;

FIG. 5 is a schematic diagram of an embodiment of a thermally conductive composite;

FIG. 6 is a schematic diagram of another embodiment of the thermally conductive composite;

FIG. 7 is a schematic diagram of an embodiment of a thermally conductive composite including porous boron nitride and a polymer.

### DETAILED DESCRIPTION

The inventors hereof have found that by combining a polymer and boron nitride particulates, where the boron nitride is in the form of nanofibers, nanotubes, or nanoplates, composites can be obtained with improved thermal conductivity. In an embodiment, the boron nitride particles are oriented in a direction substantially perpendicular to a major surface of the polymer layer, such that improved thermal conductivity is obtained. In another embodiment, a porous boron nitride having the polymer disposed in a pore of the boron nitride is provided. These materials provide other desirable properties, such as improved mechanical properties, including improved mechanical strength, resistance to failure from mechanical stress, and improved elasticity. In another embodiment, a composite having a selected dielectric constant can be provided through selection of a suitable boron nitride, such as a doped boron nitride nanotube. The composite also provides improved thermal stability, which results in the ability to avoid deformation or blistering during high temperature exposures such as during soldering and/or wire bonding. The combination of high thermal conductivity and high thermal stability is useful in devices that generate higher heat, such as chips that run at high clock speeds, high power, larger sized chips, or optoelectronic components with heat generating laser diodes. The composite can be used in a variety of circuit subassemblies, and can be used as a buildup layer, as a dielectric substrate layer in a multilayer core, or a combination thereof.

The polymer composite can comprise any suitable polymer. In an embodiment, the polymer is a dielectric polymer such as a polyimide, a polyphenylsulfone, a polyethersulfone, a polytetrafluoroethylene, a poly(arylene ether), or an epoxy. The polymer can be a homopolymer or a copolymer, and can comprise a graft or a block copolymer. The polymer can be crosslinked. Exemplary poly(arylene ether)s include poly(2,6-dimethyl-1,4-phenylene ether), poly(2,6-diethyl-1,4-phenylene ether), poly(2,6-dipropyl-1,4-phenylene ether), poly(2-methyl-6-allyl-1,4-phenylene ether), poly(di-tert-butyl-dimethoxy-1,4-phenylene ether), poly(2,6-dichloromethyl-1,4-phenylene ether, poly(2,6-dibromomethyl-1,4-phenylene ether), poly(2,6-di(2-chloroethyl)-1,4-phenylene ether), poly(2,6-ditolyl-1,4-phenylene ether), poly(2,6-dichloro-1,4-phenylene ether), poly(2,6-diphenyl-1,4-phenylene ether), and poly(2,5-dimethyl-1,4-phenylene ether). A useful poly(arylene ether) comprises 2,6-dimethyl-1,4-phenylene ether units, optionally in combination with 2,3,6-trimethyl-1,4-phenylene ether units. The polymer can be functionalized. PPE-MA from Asahi (a maleinized poly(arylene ether)), and Blendex HPP820 from Chemtura (an unmodified poly(arylene ether) are representative.

In an embodiment, the polymer can be a polybutadiene or a polyisoprene polymer suitable for use in circuit materials. A “polybutadiene or polyisoprene polymer” as used herein includes homopolymers derived from butadiene, homopolymers derived from isoprene, and copolymers derived from butadiene and/or isoprene and/or less than 50 weight percent (wt %) of a monomer co-curable with the butadiene and/or isoprene. Suitable monomers co-curable with butadiene and/or isoprene include monoethylenically unsaturated compounds such as acrylonitrile, ethacrylonitrile, methacrylonitrile, alpha-chloro acrylonitrile, beta-chloro acrylonitrile, alpha-bromoacrylonitrile, C1-6 alkyl (meth)acrylates (for example, methyl (meth)acrylate, ethyl (meth)acrylate, n-butyl (meth)acrylate, n-propyl (meth)acrylate, and isopropyl (meth)acrylate), acrylamide, methacrylamide, maleimide, N-methyl maleimide, N-ethyl maleimide, itaconic acid, (meth)acrylic acid, and combinations comprising at least one of the foregoing monoethylenically unsaturated monomers.

The polybutadiene or a polyisoprene can further comprise an elastomeric polymer. The elastomeric polymer can be co-curable with the poly(arylene ether), for example, and/or the polybutadiene or isoprene resin if present. Suitable elastomers include elastomeric block copolymers comprising a block (A) derived from an alkenyl aromatic compound and a block (B) derived from a conjugated diene. The arrangement of blocks (A) and (B) include linear and graft structures, including radial teleblock structures having branched chains. Examples of linear structures include diblock (A-B), triblock (A-B-A or B-A-B), tetrablock (A-B-A-B), and pentablock (A-B-A-B-A or B-A-B-A-B) structures as well as linear structures containing 6 or more blocks in total of A and B. Specific block copolymers include diblock, triblock, and tetrablock structures, and specifically the A-B diblock and A-B-A triblock structures.

A suitable dielectric polymer can conform to one or more industry specifications for PCBs. For example, the dielectric polymer can conform to IPC-4104B/21 specifications, or the relevant industry specifications for the particular PCB being manufactured.

Polymers that can be formulated to provide foams include polyolefins, fluoropolymers, polyimides, polyarylketones, polyarylether ketones, silicones, polyurethanes, and the like. The polymeric foam materials can be a thermoplastic (provided that it is capable of withstanding processing and use temperatures) or thermoset.

The boron nitride can be crystalline, polycrystalline, amorphous, or a combination thereof, and is in form of a nanofiber, nanotube, a nanoplate, or a combination thereof. Boron nitride in the form of a nanotube is specifically mentioned. The nano fiber can be solid. The nanotube can have one wall or can be multiwalled, and can have a hollow core. Also, a plurality of the nanofibers and/or nanotubes may have any suitable configuration. For example, the nano fibers and/or nanotubes may be randomly configured, e.g., a nonwoven mat, or they may be in a woven form.

The boron nitride can have any suitable dimensions. The boron nitride can have a cross-sectional dimension of 1 to 100 nanometers (nm), specifically 2 to 80 nm, more specifically 4 to 60 nm. The boron nitride can have a length of 100 nm to 10 millimeters (mm), specifically 200 nm to 1 mm, more specifically 400 nm to 0.1 mm. The boron nitride can have an aspect ratio, calculated as a length/cross-sectional dimension of 10 to 1,000,000, specifically 20 to 500,000, more specifically 40 to 250,000. The cross-sectional dimension can be a diameter of a fiber or tube, or a thickness of a plate. An average particle size of the boron nitride, e.g., as measured by laser light scattering, can be 10 nm to 1000 μm, specifically 20 nm to 500 μm, more specifically 40 nm to 250 μm.

The boron nitride is thermally conductive. The boron nitride can have a thermal conductivity of 1 to 2000 W/m·K, specifically 10 to 1800 W/m·K, or 100 to 1600 W/m K.

The boron nitride can be undoped, or doped to provide a desired property. For example, the boron nitride can be doped to increase the dielectric properties of the polymer, for example with silver, carbon, fluorine, or the like. Alternatively, the boron nitride can be doped to provide an n-doped or a p-doped boron nitride. The doped boron nitride can comprise an element effective to provide a boron nitride having semiconducting properties. Representative dopants include carbon, oxygen, sulfur, a halogen such as F, a transition metal such as Ag, Zr, or Ti, or a metalloid such as Si, Ge, As, Sb, or Te. A combination comprising at least one of the foregoing can be used. A content of the dopant can be 0.001 to 20 wt %, specifically 0.01 to 10 wt %, more specifically 0.1 to 1 wt %, based on a total weight of the boron nitride. Representative doped boron nitrides include Si doped BN comprising 0.1 to 10 wt % Si.

The boron nitride can be contained in the polymer layer in an amount sufficient to provide the composite suitable thermal conductivity, dielectric constant, and mechanical properties. The boron nitride can be contained in the dielectric polymer layer in an amount of 0.1 to 90 weight percent (wt %), specifically 1 to 85 wt %, more specifically 5 to 80 wt %, based on a total weight of the composite. For example, the composite can have a thermal conductivity of 1 W/m·K or more, specifically as 2 W/m·K, or more, or 4 W/m·K or more. In an embodiment, the composite can have a thermal conductivity of 1 to 2000 W/m·K, specifically 1 to 1000 W/m·K, or 1 to 100 W/m·K. The composite can have a dielectric constant of 1.5 to 15, specifically 3 to 12, more specifically 4 to 10. The composite can have a coefficient of thermal expansion of 1 to 50 ppm/° C., specifically 2 to 40 ppm/° C., more specifically 4 to 30 ppm/° C.

In an embodiment, a porous boron nitride is used as shown schematically in FIG. 7. In one aspect, the polymer 500 can be disposed in the pores of the porous boron nitride 600. The polymer can completely or partially fill the pores. It is to be understood that the polymer can optionally fully or partially coat and surround the porous boron nitride 600. A porosity of the boron nitride can be 1 to 99 volume percent (vol %), specifically 2 to 98 vol %, more specifically 4 to 96 vol %. A pore size of the porous boron nitride can be 1 nm to 1000 nm, specifically 2 nm to 500 nm, more specifically 4 nm to 250 nm. The polymer can be present in an amount of 0.1 to 90 weight percent (wt %), specifically 1 to 85 wt %, more specifically 5 to 80 wt %, based on a total weight of the composite.

The properties of the composite can be isotropic or anisotropic. While not wanting to be bound by theory, it is understood that orientation of the boron nitride provides anisotropic properties. The boron nitride can be randomly oriented, or can be oriented in a selected direction. Orientation in a direction perpendicular to a major surface of the composite, i.e., in a thickness or through-plane direction as shown in FIG. 5 for an embodiment in which boron nitride nanotubes 200 are oriented in a through-plane direction of the composite 100, is specifically mentioned. Alternatively, an embodiment in which the boron nitride 300 is randomly oriented in the composite 400 is shown in FIG. 6. An in-plane thermal conductivity and a through-plane conductivity of the composite can each be independently selected, and can each independently be 1 to 2000 W/m·K, specifically 10 to 1800 W/m·K, or 100 to 1600 W/m·K. In an embodiment the through-plane conductivity is 10 to 10,000 times greater than the in-plane conductivity, specifically 100 to 1000 greater. An in-plane coefficient of thermal expansion and a through-plane coefficient of thermal expansion of the composite can each be independently selected, and can each independently be 1 to 50 ppm/° C., specifically 2 to 40 ppm/° C., more specifically 4 to 30 ppm/° C.

The composite can have a dissipation factor of less than or equal to 0.02 measured at 10 gigahertz; specifically less than or equal to 0.01 measured at 10 gigahertz; more specifically less than or equal to 0.005 measured at 10 gigahertz.

The composite has a relatively low modulus and high elongation. This is particularly helpful in the reliability of copper interconnects as it prevents excessive stress from being imparted on the walls of copper plated vias as the parts are thermally cycled. In one embodiment, the tensile modulus of the composite is less than 3000 megaPascals (MPa), specifically 100 to 3000 MPa, more specifically 200 to 2500 MPa. In another embodiment, the elongation of the dielectric material is greater than 5%.

The composite can further have low moisture absorption, which results in a substrate that is less sensitive to environmental conditions both in use and during storage. In an embodiment, the moisture absorption is 0.05 to 0.3% at 24 hours immersion in water at 23° C.

The composite can further comprise an additional filler, for example a filler to adjust the dielectric properties of the composite. A low coefficient of expansion filler, such as glass beads, silica or ground micro-glass fibers, can be used. A thermally stable fiber, such as an aromatic polyamide, or a polyacrylonitrile can be used. Representative fillers include titanium dioxide (rutile and anatase), barium titanate, strontium titanate, fused amorphous silica, corundum, wollastonite, aramide fibers (e.g., KEVLAR™ from DuPont), fiberglass, Ba₂Ti₉O₂₀, quartz, aluminum nitride, silicon carbide, beryllia, alumina, magnesia, mica, talcs, nanoclays, aluminosilicates (natural and synthetic), and fumed silicon dioxide (e.g., Cab-O-Sil, available from Cabot Corporation), each of which can be used alone or in combination.

The fillers can be in the form of solid, porous, or hollow particles. The particle size of the filler affects a number of important properties including coefficient of thermal expansion, modulus, elongation, and flame resistance. In an embodiment, the filler has an average particle size of 0.1 to 15 micrometers, specifically 0.2 to 10 micrometers. A combination of fillers having a bimodal, trimodal, or higher average particle size distribution can be used. The filler can be included in an amount of 0.1 to 80 wt %, specifically 1 to 65 wt %, or 5 to 50 wt %, based on a total weight of the composite.

To improve adhesion between the boron nitride, the filler if present, and the polymer, a coupling agent such as a silane, a zirconate, or a titanate can be used. The boron nitride and the filler, if present, can be pretreated, or the coupling agent can be included in the polymer. The coupling agent, when present, can be present in amounts of 0.01 to 2.0 wt %, based on the total weight of the composite.

The polymer can further optionally comprise additives such as cure initiators, crosslinking agents, viscosity modifiers, wetting agents, flame retardants, and antioxidants. The particular choice of additives depends upon the particular application of the composite, and the desired properties for that application, and are selected so as to enhance or not substantially adversely affect the electrical properties of the circuit subassemblies, such as thermal conductivity, dielectric constant, dissipation factor, dielectric loss, and/or other desired properties.

Exemplary cure initiators include those useful in initiating cure (cross-linking) of the polymers, in the composite. Examples include, but are not limited to, azides, peroxides, sulfur, and sulfur derivatives. Free radical initiators are especially desirable as cure initiators. Examples of free radical initiators include peroxides, hydroperoxides, and non-peroxide initiators such as 2,3-dimethyl-2, 3-diphenyl butane. Examples of peroxide curing agents include dicumyl peroxide, alpha, alpha-di(t-butylperoxy)-m,p-diisopropylbenzene, 2,5-dimethyl-2,5-di(t-butylperoxy)hexane-3, and 2,5-dimethyl-2,5-di(t-butylperoxy)hexyne-3, and mixtures comprising one or more of the foregoing cure initiators. The cure initiator, when used, can be present in an amount of 0.01 wt % to 5 wt %, based on the total weight of the composite.

Crosslinking agents are reactive monomers or polymers that increase the cross-link density upon cure of the dielectric material. In one embodiment, such reactive monomers or polymers are capable of co-reacting with the polymer in the composite. Examples of suitable reactive monomers include styrene, divinyl benzene, vinyl toluene, divinyl benzene, triallylcyanurate, diallylphthalate, and multifunctional acrylate monomers (such as Sartomer compounds available from Sartomer Co.), among others, all of which are commercially available. Useful amounts of crosslinking agents are 0.1 to 50 wt %, based on the total weight of the composite.

Exemplary antioxidants include radical scavengers and metal deactivators. A non-limiting example of a free radical scavenger is poly[[6-(1,1,3,3-tetramethylbutyl)amino-s-triazine-2,4-dyil][(2,2,6,6,-tetramethyl-4-piperidypimino]hexamethylene[(2,2,6,6-tetramethyl-4-piperidypimino]], commercially available from Ciba Chemicals under the tradename Chimassorb 944. A non-limiting example of a metal deactivator is 2,2-oxalyldiamido bis[ethyl 3-(3,5-di-t-butyl-4-hydroxyphenyl)propionate] commercially available from Uniroyal Chemical (Middlebury, Conn.) under the tradename Naugard XL-1. A single antioxidant or a mixture of two or more antioxidants can be used. Antioxidants are typically present in amounts of up to 3 wt %, specifically 0.5 to 2.0 wt %, based on the total weight of the composite.

Coupling agents can be present to promote the formation of or participate in covalent bonds connecting a metal surface or filler surface with a polymer. Exemplary coupling agents include 3-mercaptopropylmethyldimethoxy silane and 3-mercaptopropyltrimethoxy silane and hexamethylenedisilazanes.

Representative flame retardant additives include bromine, phosphorus, and metal oxide-containing flame retardants. Suitable bromine containing flame retardants are commercially available from, for example, Albemarle Corporation under trade names Saytex BT-93 W (ethylenebistetrabromonaphthalamide), Saytex 120 (tetradecaboromodiphenoxybenzene), and Great Lake under trade name BC-52, BC-58, Esschem Inc under the trade name FR1025. Suitable phosphorus containing flame retardants include various organic phosphorous-based compounds, for example an aromatic phosphate of the formula (GO)₃P═O, wherein each G is independently an C1-36 alkyl, cycloalkyl, aryl, alkylaryl, or arylalkyl group, provided that at least one G is an aromatic group. Two of the G groups can be joined together to provide a cyclic group, for example, diphenyl pentaerythritol diphosphate. Other suitable aromatic phosphates can be, for example, phenyl bis(dodecyl) phosphate, phenyl bis(neopentyl) phosphate, phenyl bis(3,5,5′-trimethylhexyl) phosphate, ethyl diphenyl phosphate, 2-ethylhexyl di(p-tolyl) phosphate, bis(2-ethylhexyl) p-tolyl phosphate, tritolyl phosphate, bis(2-ethylhexyl) phenyl phosphate, tri(nonylphenyl) phosphate, bis(dodecyl) p-tolyl phosphate, dibutyl phenyl phosphate, 2-chloroethyl diphenyl phosphate, p-tolyl bis(2,5,5′-trimethylhexyl) phosphate, 2-ethylhexyl diphenyl phosphate, or the like. A specific aromatic phosphate is one in which each G is aromatic, for example, triphenyl phosphate, tricresyl phosphate, isopropylated triphenyl phosphate, and the like. Examples of suitable di- or polyfunctional aromatic phosphorous-containing compounds include resorcinol tetraphenyl diphosphate (RDP), the bis(diphenyl) phosphate of hydroquinone and the bis(diphenyl) phosphate of bisphenol-A, respectively, their oligomeric and polymeric counterparts, and the like. Metal phosphinate salts can also be used. Examples of phosphinates are phosphinate salts such as for example alicylic phosphinate salts and phosphinate esters. Further examples of phosphinates are diphosphinic acids, dimethylphosphinic acid, ethylmethylphosphinic acid, diethylphosphinic acid, and the salts of these acids, such as for example the aluminum salts and the zinc salts. Examples of phosphine oxides are isobutylbis(hydroxyalkyl) phosphine oxide and 1,4-diisobutylene-2,3,5,6-tetrahydroxy-1,4-diphosphine oxide or 1,4-diisobutylene-1,4-diphosphoryl-2,3,5,6-tetrahydroxycyclohexane. Further examples of phosphorous-containing compounds are NH1197® (Great Lakes), NH1511® (Great Lakes), NcendX P-30® (Albemarle), Hostaflam OP5500® (Clariant), Hostaflam OP910® (Clariant), EXOLIT 935 (Clariant), and Cyagard RF 1204®, Cyagard RF 1241® and Cyagard RF 1243R (Cyagard are products of Cytec Industries). In a particularly advantageous embodiment, a halogen-free composite has excellent flame retardance when used with EXOLIT 935 (an aluminum phosphinate). Still other flame retardants include melamine polyphosphate, melamine cyanurate, Melam, Melon, Melem, guanidines, phosphazanes, silazanes, DOPO (9,10-dihydro-9-oxa-10 phosphenathrene-10-oxide), and DOPO (10-5 dihydroxyphenyl, 10-H-9 oxaphosphaphenanthrenelo-oxide). Suitable metal oxide flame retardants are magnesium hydroxide, aluminum hydroxide, zinc stannate, and boron oxide. The flame retardant agents can be present in amounts known in the art for the various types of agents.

The composite can be manufactured by combining the polymer or a prepolymer composition with the boron nitride to manufacture the thermally conductive composite. The combining can be by any suitable method, such as blending, mixing, or stirring. In an embodiment, the components of the composition used to form the composite, including the polymer and the boron nitride, can be combined by being dissolved and/or suspended in a solvent to provide a coating mixture or solution. The solvent is selected so as to dissolve the polymer or pre-polymer composition, disperse the boron nitride and any other optional filler that can be present, and to have a convenient evaporation rate for forming and drying. A non-exclusive list of possible solvents is xylene, toluene, methyl ethyl ketone, methyl isobutyl ketone, hexane, and higher liquid linear alkanes, such as heptane, octane, nonane, and the like, cyclohexane, isophorone, and various terpene-based solvents. Specific exemplary solvents include xylene, toluene, methyl ethyl ketone, methyl isobutyl ketone, and hexane, and still more specifically xylene and toluene. The concentration of the components of the composition in the solution or dispersion is not critical and will depend on the solubility of the components, the filler level used, the method of application, and other factors. In general, the solution comprises 10 to 50 wt % solids (all components other than the solvent), more specifically 15 to 40 wt % solids, based on the total weight of the solution. The coating mixture can be formed onto a carrier from which it is later released, or alternatively onto a substrate such as a conductive metal layer that will later be formed into a layer of a circuit structure.

After the layer is formed, e.g., by casting, solvent is allowed to evaporate under ambient conditions, or by forced or heated air, to form the composite. The layer can be uncured or partially cured (B-staged) in the drying process, or the layer can be partially or fully cured, if desired, after drying. The layer can be heated, for example at 20 to 200° C., specifically 30 to 150° C., more specifically 40 to 100° C. The resulting composite can be stored prior to lamination (for example to a foam) and cure, partially cured and then stored, or laminated and fully cured after buildup.

Alternatively, for example if a thermoset is used, the method can comprise polymerizing a pre-polymer composition to manufacture the thermally conductive composite. In an embodiment in which the boron nitride is a porous boron nitride, the polymer may be formed, e.g., polymerized, in a pore of the porous boron nitride.

In another embodiment, where a foam is formed, the composite is foamed by methods known in the art, for example mechanical frothing, and casting to form a layer; or by chemical or physical blowing agents before or after the layer is formed.

The thickness of the composite layer will depend on its intended use. In an embodiment, the thickness of the composite is 5 to 1000 micrometers, specifically 5 to 500 micrometers, more specifically 5 to 400 micrometers. In another embodiment, when used as a dielectric substrate layer, the thickness of the composite is 25 to 400 micrometers, specifically 50 micrometers to 200 micrometers, and more specifically 75 micrometers to 150 micrometers.

The composite can be used in a variety of circuit materials. As used herein, a circuit material is an article used in the manufacture of circuits and multi-layer circuits, and includes circuit subassemblies, bond plies, resin-coated conductive layers, unclad dielectric layers, free films, and cover films. Circuit subassemblies include circuit laminates having a conductive layer, e.g., copper, fixedly attached to a dielectric layer. Double clad circuit laminates have two conductive layers, one on each side of the dielectric layer. Patterning a conductive layer of a laminate, for example by etching, provides a circuit. Multilayer circuits comprise a plurality of conductive layers, at least one of which contains a conductive wiring pattern. Typically, multilayer circuits are formed by laminating one or more circuits together using bond plies, by building up additional layers with resin coated conductive layers that are subsequently etched, or by building up additional layers by adding unclad dielectric layers followed by additive metallization. After forming the multilayer circuit, known hole-forming and plating technologies can be used to produce useful electrical pathways between conductive layers.

Useful conductive layers for the formation of the circuit materials circuit laminates can include, without limitation, stainless steel, copper, gold, silver, aluminum, zinc, tin, lead, transition metals, and alloys comprising at least one of the foregoing, with copper being exemplary. Suitable conductive layers include a thin layer of a conductive metal such as a copper foil presently used in the formation of circuits, for example, electrodeposited copper foils.

In an embodiment, the laminate is formed by placing one or more layers of the dielectric composite material between one or two sheets of coated or uncoated conductive layers (an adhesive layer can be disposed between at least one conductive layer and at least one dielectric substrate layer) to form a circuit substrate. The conductive layer can be in direct contact with the dielectric substrate layer, specifically without an intervening layer. Alternatively, an adhesive or bond ply layer can be located between the conductive layer and the dielectric layer. The bond ply layer can be less than 10 percent of the thickness of the dielectric layer.

The layered material can then be placed in a press, e.g. a vacuum press, under a pressure and temperature and for duration of time suitable to bond the layers and form a laminate. Lamination and curing can be by a one-step process, for example using a vacuum press, or by a multiple-step process. In an exemplary one-step process, for a PTFE polymer matrix, the layered material can be placed in a press, brought up to laminating pressure (e.g., about 150 to about 400 psi) and heated to laminating temperature (e.g., about 260 to about 390° C.). The laminating temperature and pressure are maintained for the desired soak time, i.e., about 20 minutes, and thereafter cooled (while still under pressure) to below about 150° C.

In an exemplary multiple-step process, a peroxide cure step at temperatures of about 150° C. to about 200° C. can be conducted, and the partially cured stack can then be subjected to a high-energy electron beam irradiation cure (E-beam cure) or a high temperature cure step under an inert atmosphere. Use of a two-stage cure can impart an unusually high degree of cross-linking to the resulting laminate. The temperature used in the second stage is typically about 250° C. to about 300° C., or the decomposition temperature of the polymer. This high temperature cure can be carried out in an oven but can also be performed in a press, namely as a continuation of the initial lamination and cure step. Particular lamination temperatures and pressures will depend upon the particular adhesive composition and the substrate composition, and are readily ascertainable by one of ordinary skill in the art without undue experimentation.

In FIG. 1, an exemplary circuit subassembly is illustrated. The subassembly is a single clad laminate 10 comprising a conductive metal layer 12 disposed on and in contact with a dielectric substrate layer 14. The dielectric substrate layer 14 comprises the crosslinked fluoropolymer and can optionally also include a particulate filler such that a dielectric composite material is formed thereby. An optional glass web (not shown) can be present in dielectric substrate layer 14. It is to be understood that in all of the embodiments described herein, the various layers can fully or partially cover each other, and additional conductive layers, patterned circuit layers, and dielectric layers can also be present. Optional adhesive (bond ply) layers (not shown) can also be present, and can be uncured or partially cured. Many different multi-layer circuit configurations can be formed using the above laminates.

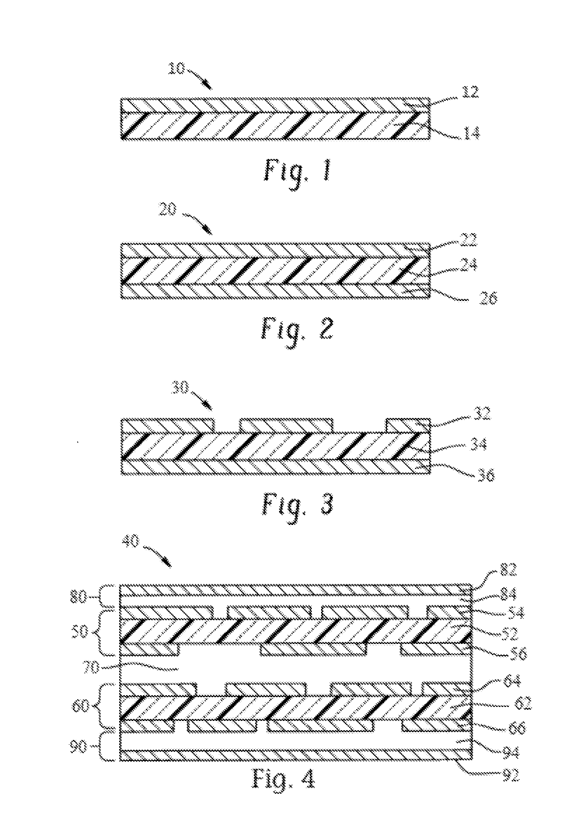

Another embodiment of a multilayer circuit assembly is shown at 20 in FIG. 2. Double clad circuit layer 20 comprises conductive layers 22, 26 disposed on opposite sides of a dielectric substrate layer 24. The dielectric substrate layer can include a filler. Dielectric substrate layer 24 can also comprise a woven or nonwoven web (not shown).

A circuit subassembly 30 is shown in FIG. 3, comprising a circuit layer 32 and a conductive layer 36 disposed on opposite sides of a dielectric substrate layer 34. Dielectric substrate layer 34 can also comprise a woven or nonwoven web (not shown).

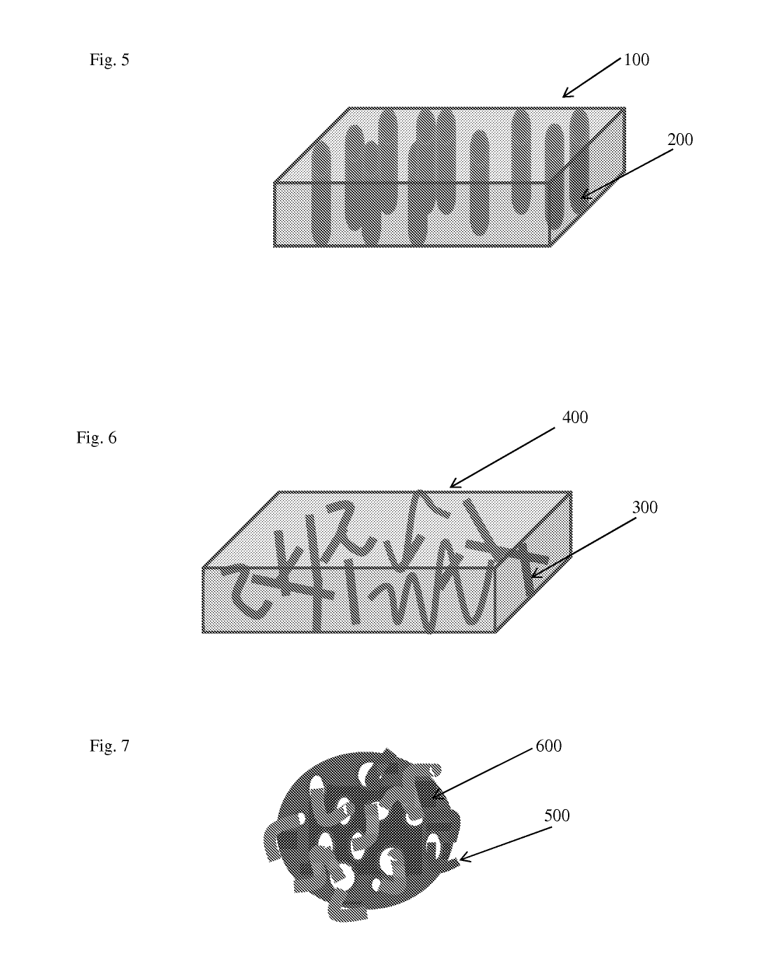

FIG. 4 shows an exemplary multilayer circuit assembly 40 having a first double clad circuit 50, a second double clad circuit 60, and a bond ply 70 disposed therebetween. Double clad circuit 50 comprises a dielectric substrate 52 disposed between two conductive circuit layers 54, 56. Double clad circuit 60 comprises a dielectric substrate 62 disposed between two conductive circuit layers 64, 66. One or both of dielectric substrates 52, 62 can comprise borosilicate microspheres as a filler. Each dielectric substrate layer 52, 62 can comprise a woven or nonwoven glass reinforcement (not shown). Two cap layers 80, 90 are also shown. Each cap layer 80, 90, respectively include a conductive layer 82, 92 disposed on a bond ply layer 84, 94.

In another embodiment, the composite is in the form of a foam. The foam can have an open-cell or a closed-cell structure.

### Prophetic Example

Poly(phenylene ether) (NORYL 640-111, 1 gram (g)), butadiene-styrene copolymer (Ricon 184 MA-6, 1 g), a curing agent (Perkadox, 0.5 g), and boron nitride nanotubes (1 g), are combined in xylenes and then cast to form a layer, and the layer dried to form a composite. The composite has desirable thermal conductivity, dielectric properties, and mechanical properties.

The invention is further illustrated by the following embodiments, which do not limit the claims.

Embodiment 1. A thermally conductive composite comprising: a polymer; and boron nitride, wherein the boron nitride is in a form of a nanofiber, a nanotube, a nanoplate, or a combination thereof.

Embodiment 2. The thermally conductive composite of Embodiment 1, wherein the boron nitride is in a form of a nanofiber or a nanotube.

Embodiment 3. The thermally conductive composite of any one or more of Embodiments 1-2, wherein the boron nitride is in a form of nanofiber, and wherein the nanofiber is in a woven form.

Embodiment 4. The thermally conductive composite of any one or more of Embodiments 1-3, wherein the boron nitride has a cross-sectional dimension of 1 to 100 nanometers.

Embodiment 5. The thermally conductive composite of any one or more of Embodiments 1-4, wherein the boron nitride has a length of 100 nanometers to 10 millimeters.

Embodiment 6. The thermally conductive composite of any one or more of Embodiments 1-5, wherein the boron nitride has an aspect ratio of 10 to 1,000,000.

Embodiment 7. The thermally conductive composite of any one or more of Embodiments 1-6, wherein the boron nitride extends in a direction substantially perpendicular to a major surface of the polymer layer.

Embodiment 8. A thermally conductive composite comprising: a boron nitride comprising pores; and a polymer disposed in a pore of the boron nitride.

Embodiment 9. The thermally conductive composite of Embodiment 8, wherein the boron nitride has an average pore size of 5 to 1000 nanometers.

Embodiment 10. The thermally conductive composite of any one or more of Embodiments 8-9, wherein the boron nitride is a doped boron nitride.

Embodiment 11. The thermally conductive composite of any one or more of Embodiments 8-10, wherein the composite is in the form of a layer.

Embodiment 12. A method of manufacturing the thermally conductive composite of any one or more of Embodiments 1-11, the method comprising: combining a polymer or a pre-polymer composition with boron nitride and a solvent to form a mixture; casting the mixture to form a layer; and removing the solvent to manufacture the thermally conductive composite.

Embodiment 13. The method of Embodiment 12, further comprising crosslinking the polymer.

Embodiment 14. The method of any one or more of Embodiments 12-13, further comprising foaming the polymer.

Embodiment 15. The method of any one or more of Embodiments 12-14, wherein the boron nitride is a porous boron nitride, and further comprising polymerizing the pre-polymer composition in a pore of the porous boron nitride.

Embodiment 16. A circuit material comprising the thermally conductive composite of any one or more of Embodiments 1-15, optionally disposed on a conductive layer.

Embodiment 17. A printed circuit board comprising the thermally conductive composite of any one or more of Embodiments 1-15 disposed on a circuit.

“Alkyl” as used herein means a straight or branched chain saturated aliphatic hydrocarbon having the specified number of carbon atoms, specifically 1 to 12 carbon atoms, more specifically 1 to 6 carbon atoms. Alkyl groups include, for example, groups having from 1 to 50 carbon atoms (C1 to C50 alkyl).

“Aryl” means a cyclic moiety in which all ring members are carbon and at least one ring is aromatic, the moiety having the specified number of carbon atoms, specifically 6 to 24 carbon atoms, more specifically 6 to 12 carbon atoms. More than one ring can be present, and any additional rings can be independently aromatic, saturated or partially unsaturated, and can be fused, pendant, spirocyclic or a combination thereof.

“Transition metal” as used herein refers to an element of Groups 3 to 11 of the Periodic Table of the Elements.

Ranges disclosed herein are inclusive of the endpoints and all intermediate values, and independently combinable. Furthermore, the terms “first,” “second,” and the like, herein do not denote any order, quantity, or importance, but rather are used to distinguish one element from another, and the terms “a” and “an” herein do not denote a limitation of quantity, but rather denote the presence of at least one of the referenced item. “Or” means “and/or.” As used herein, the terms sheet, film, plate, and layer, are used interchangeably, and are not intended to denote size. Further as used herein, a dissolution medium is inclusive of a dissolution medium. All references are incorporated herein by reference in their entirety.

While the invention has been described with reference to several embodiments thereof, it will be understood by those skilled in the art that various changes can be made and equivalents can be substituted for elements thereof without departing from the scope of the invention. In addition, many modifications can be made to adapt a particular situation or material to the teachings of the invention without departing from the essential scope thereof. Therefore, it is intended that the invention not be limited to the particular embodiments disclosed as the best mode contemplated for carrying out this invention, but that the invention will include all embodiments falling within the scope of the appended claims.

1. A thermally conductive composite comprising:
a polymer; and
boron nitride, wherein the boron nitride is in a form of a nanofiber.

2. (canceled)

3. The thermally conductive composite of claim 1, wherein the nanofiber is in a woven form.

4. The thermally conductive composite of claim 1, wherein the boron nitride nanofiber has a cross-sectional dimension of 1 to 100 nanometers.

5. The thermally conductive composite of claim 1, wherein the boron nitride nanofiber has a length of 100 nanometers to 10 millimeters.

6. The thermally conductive composite of claim 1, wherein the boron nitride nanofiber has an aspect ratio of 10 to 1,000,000.

7. The thermally conductive composite of claim 1, wherein the boron nitride nanofibers extends in a direction substantially perpendicular to a major surface of the polymer layer.

8. A thermally conductive composite comprising:
a boron nitride comprising pores; and
a polymer disposed in a pore of the boron nitride.

9. The thermally conductive composite of claim 8, wherein the boron nitride has an average pore size of 5 to 1000 nanometers.

10. The thermally conductive composite claim 8, wherein the boron nitride is a doped boron nitride.

11. The thermally conductive composite of claim 8, wherein the composite is in the form of a layer.

12. A method of manufacturing the thermally conductive composite of claim 1, the method comprising:
combining a polymer or a pre-polymer composition with the boron nitride nanofibers and a solvent to form a mixture;
casting the mixture to form a layer; and
removing the solvent to manufacture the thermally conductive composite.

13. The method of claim 12, further comprising crosslinking the polymer.

14. The method of claim 12, further comprising foaming the polymer.

15. The method of claim 12, wherein the boron nitride is a porous boron nitride.

16. A circuit material comprising the thermally conductive composite of claim 1, optionally disposed on a conductive layer.

17. A printed circuit board comprising the thermally conductive composite of claim 1, optionally disposed on a conductive layer.

18. A circuit material comprising the thermally conductive composite of claim 8, optionally disposed on a conductive layer.

19. The thermally conductive composite claim 1, wherein the boron nitride is a doped boron nitride.

20. The method of claim 12, further comprising polymerizing the prepolymer composition.

21. The method of claim 15, further comprising polymerizing the pre-polymer composition in a pore of the porous boron nitride.
